(19) United States
(12) Patent Application Publication
(10) Pub. No.: US 2023/0189946 A1
(43) Pub. Date: Jun. 22, 2023

(54) METHOD FOR DEPOSITING A COATING ON A SUBSTRATE

(71) Applicant: OMEGA SA, Bienne (CH)

(72) Inventors: Loïc Curchod, Lausanne (CH); Simon Springer, Berne (CH); Stéphane Lauper, Cortaillod (CH); Ahmad Odeh, Renens (CH); Marion Gstalter, Grand'Combe Châteleu (FR); Loïc Oberson, Morges (CH); Gregory Kissling, La Neuveville (CH)

(73) Assignee: OMEGA SA, Bienne (CH)

(21) Appl. No.: 17/989,854

(22) Filed: Nov. 18, 2022

(30) Foreign Application Priority Data
Dec. 21, 2021 (EP) 21216468.5

(51) Int. Cl. A44C 27/00; C23C 14/34; B23K 26/0622; B23K 26/352

(52) U.S. Cl. CPC A44C 27/006; C23C 14/3442; B23K 26/0622; B23K 26/352

(57) ABSTRACT

A method for depositing a coating on a substrate (100), including a step of depositing a thin intermetallic layer (110) on the substrate (100), so as to obtain, at the end of this step, an external part (10) having a predetermined final colour.

### CROSS REFERENCE TO RELATED APPLICATIONS

This application claims priority to European Patent Application No. 21216468.5 filed Dec. 21, 2021, the entire contents of which are incorporated herein by reference.

### TECHNICAL FIELD OF THE INVENTION

The invention falls within the field of materials, and particularly materials defining the external appearance of external parts of timepieces, jewellery, fashion items, or more generally miscellaneous objects.

More particularly, the invention relates to a method for depositing a coating on a substrate.

### TECHNOLOGICAL BACKGROUND

Depositions of thin layers in a controlled atmosphere are commonly used in industry in general and in the watchmaking and jewellery fields in particular, to produce coatings having aesthetic and/or technical applications.

For aesthetic applications, the thin layers deposited may consist of noble metals, such as gold (Au) and silver (Ag), or noble metal alloys. These noble metal alloys often consist of a combination of gold, silver and copper (Cu), with possibly additions of platinum (Pt) or other similar metals. In these noble metal alloys, atoms form metallic bonds that are at the origin of the colour of the alloy and of its malleability.

Some of the thin layer deposition methods commonly used are the Physical Vapour Deposition (PVD) methods particularly comprising the cathodic sputtering method and the evaporation methods; the Chemical Vapour Deposition (CVD) methods; the galvanic growth metal deposition methods; and the Atomic Layer Deposition (ALD) methods.

Furthermore, intermetallic compounds exist, particularly of noble metals, offering a broader palette of colours in relation to the aforementioned standard noble alloys. For example, the yellow Pt—Al, orange or pink Pt—Al—Cu, blue Au—Al, violet Au—In intermetallic compounds.

In these intermetallic compounds, the atoms form strong covalent bonds that are at the origin of the particular colours of these compounds, but that make them hard and brittle in their massive form. These intermetallic compounds are therefore difficult to use and effectively rarely used in their massive form because not very malleable and difficult to shape.

These intermetallic compounds may nevertheless be used in the form of more or less thin layers by implementing one of the aforementioned vacuum thin layer deposition methods.

For example, these deposition methods may be implemented to deposit thin layers of intermetallic compounds formed from metals such as Au, Al, Cu, In or Pt, such as the compounds AuAl₂ and PtAl₂.

Nevertheless, the thin layers of intermetallic compounds deposited by these methods are outside thermodynamic equilibrium and have a mainly amorphous phase that does not have the desired colour that said intermetallic compounds of the same compositions have in their massive and crystalline form, but typically a grey colour that is not particularly aesthetically pleasing.

Indeed, the thermodynamic state of intermetallic compounds, and in particular their crystallinity and/or the presence of various phases, has a major impact on their colour for a given composition.

A step of annealing the layer in situ during the deposition method, typically at 400° C., is therefore implemented to cause a crystallisation at least partial of the intermetallic compound layer thus deposited and obtain the colouration of the layer that is specific to the crystalline phase of said intermetallic compound for the given composition.

The thin layers of intermetallic compounds in practice remain very rarely used insofar as, although they offer interesting alternatives in terms of choice of colours in relation to thin layers of standard noble alloys, the implementation of the method for depositing them is long and complex due to the fact of needing to perform an in situ annealing of the thin layers.

### SUMMARY OF THE INVENTION

The present invention resolves the aforementioned drawbacks.

To this end, the invention relates to a method for depositing a coating on a substrate, said method including a step of depositing, typically at least of 100° C., a thin intermetallic layer on said substrate, said thin layer being formed of an intermetallic compound the composition of which is chosen so as to obtain, at the end of this step, an external part of a timepiece, jewellery or fashion items having a predetermined final colour.

As the final colour of the intermetallic layer is obtained directly after the step of depositing the thin intermetallic colour, in a mainly amorphous, slightly crystalline, phase, it is not necessary to apply an annealing step to the external part to crystallise the thin intermetallic layer.

Advantageously, thanks to the invention, the external part is produced in a considerably short time. Moreover, the method may be implemented on substrates sensitive to high temperatures, that is to say, substrates for which the implementation of an annealing step would generate a plastic deformation, or even a breakage.

In particular implementations, the invention may further include one or more of the following features, taken alone or according to any technically possible combinations.

In particular implementations, the step of depositing the thin intermetallic layer is performed by implementing a PVD deposition method from ionic or cathodic sputtering, thermal evaporation, arc or electron beam evaporation, or pulsed laser beam ablation.

In particular implementations, the deposition of the thin layer is performed from at least one target consisting of a composite of at least two metals or of at least two targets of different pure metals. In the case of the use of pure metal targets, the deposition of the thin layer is performed by co-sputtering, that is to say by simultaneous cathodic sputtering of at least two different pure metal targets, the intermetallic compound then forming when encountering at least two atom flows on the substrate. Alternatively, the deposition of the thin layer is performed by co-evaporation, i.e. by simultaneous evaporation of at least two targets (for example in the form of powder or granules in a crucible or equivalent) of two different pure metals, the intermetallic compound then forming when encountering atom flows coming from at least two targets on the substrate. The powers applied on the at least two targets are selected independently so that the sputtering rates of the at least two different metals result in the desired layer composition. Nevertheless, the rate for depositing the metals varies depending on the wear of the corresponding targets and the composition of the derivative layer as a consequence as said targets are used. These variations of deposition rates may be compensated by a correction of the power applied on each of the targets depending on their wear, either manually on the basis of a calibration table or automatically thanks to a feedback loop based on an in situ measurement (for example, a spectral measurement of the optical emission of the plasma in the case of the cathodic sputtering).

In the case of the use of a composite target, the composition of said target is selected in such a way as to directly obtain the desired layer composition on the substrate, with the advantage of not depending on the wear of said composite target.

In particular implementations, the deposition step is performed so that the thin intermetallic layer has a thickness between 20 and 1000 nm, preferably between 200 and 500 nm, and more preferably of 300 nm.

In particular implementations, the method comprises a step of localised annealing on a predetermined area of the thin intermetallic layer so as to locally crystallise it and locally modify the final colour of the external part. Thus, a contrast of colours is obtained between the non-annealed area, slightly amorphous and grey, and the annealed area, crystallised and grey.

In particular implementations, the localised annealing step is performed by means of a laser the beam of which has a diameter between 10 μm and 100 μm, or even 50 μm and 100 μm.

In particular implementations, the localised annealing step is performed by means of a laser configured to emit pulses the duration of which is between 4 ns and 350 ns, of variable frequency between 10 kHz and 1 MHz.

In particular implementations, the localised annealing operation is performed at ambient atmosphere or in an enclosure in a protective atmosphere of an inert gas, i.e. argon (Ar), or in a vacuum in order to avoid any chemical interaction between the thin intermetallic layer and the atmosphere.

In particular implementations, the step of depositing the thin intermetallic layer may be preceded by a surface structuring step wherein the surface of the substrate is structured, for example on only one portion.

In particular implementations, during the structuring step, a portion of the surface of the substrate is structured, said portion corresponding to the predetermined area subjected to the localised annealing step, a surface appearance contrast then adding to the colour contrast.

In particular implementations, during the structuring step, the structuring is performed on the entire surface of the substrate that will be covered by the thin intermetallic layer.

In particular implementations, the method comprises, after the step of depositing a thin intermetallic layer and the possible step of localised annealing, a step of depositing a layer for protecting the thin intermetallic layer against environmental hazards.

In particular implementations, during the step of depositing a protective layer, the thin intermetallic layer is covered by a stack of thin dielectric layers deposited by one or more vacuum deposition methods, such as by PVD, CVD or ALD.

In particular implementations, during the step of depositing a protective layer, the composition and the thickness of the thin dielectric layers of the protective stack are specifically selected to conserve the original colour of the thin intermetallic layer or to advantageously modify the colour of the thin intermetallic layer in a chosen direction.

In particular, the thicknesses and compositions of the thin dielectric layers forming the protective stack are selected so that the interfering optical effects of said thin dielectric layers advantageously aesthetically modify the colour of the thin intermetallic layer, for example by increasing the saturation of the colour or by correcting the hue in a chosen direction.

In particular implementations, the protective layer is a translucent polymer layer deposited by spraying or any other method known by the person skilled in the art.

In particular implementations, the protective layer is a composite layer with combinations of polymer and dielectric layers deposited by the techniques known by the person skilled in the art.

The invention also relates, according to another aspect, to a timepiece component comprising a substrate comprising a coating deposited by implementing the aforementioned method, said timepiece component having a predetermined final colour.

### BRIEF DESCRIPTION OF THE FIGURES

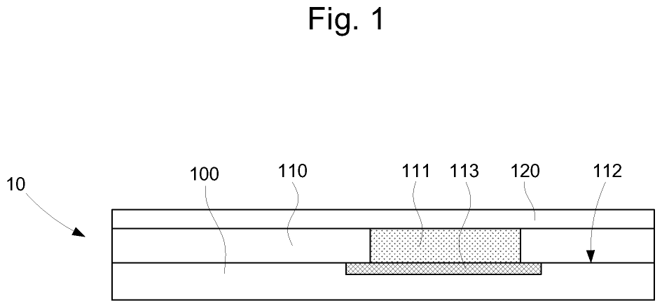

Other features and advantages of the invention will become apparent upon reading the following detailed description given by way of non-limiting example, with reference to FIG. 1 schematically showing a sectional view of a timepiece component, such as an external part, obtained by implementing a method for depositing an intermetallic layer according to the present invention.

### DETAILED DESCRIPTION OF THE INVENTION

The present invention relates to a method for depositing a coating on a substrate 100, said method including a step of depositing a thin intermetallic layer 110 on the substrate 100 so as to obtain an external part 10 of a timepiece, jewellery or fashion items. In particular, such an external part 10 may advantageously form a timepiece component.

The substrate 100 may be produced in any suitable material, such as in metallic material, ceramic, etc.

The step of depositing the thin intermetallic layer 110 is implemented so that once completed, the colour of the thin layer deposited corresponds to a predetermined colour. More particularly, the step of depositing the thin intermetallic layer 110 is implemented so that at the end of this step, the external part 10 has a predetermined final colour corresponding to said predetermined colour of the thin intermetallic layer 110 deposited.

In other words, the method is implemented so that it is not necessary to perform a step of annealing the external part 10 to crystallise the intermetallic layer 110. More specifically, the composition of the thin intermetallic layer 110 is selected so that it has the predetermined colour directly in its mainly amorphous and slightly crystalline phase, such that deposited at a temperature below 100° C. with the deposition method selected.

The step of depositing the thin intermetallic layer 110 is performed by implementing a PVD deposition method and more particularly by implementing one of the following methods: ionic or cathodic sputtering, thermal evaporation, arc or electron beam evaporation, or pulsed laser beam ablation.

The deposition of the thin intermetallic layer 110 is performed from at least two targets each consisting of a specific metal and/or from at least one target consisting of a composite of at least two metals.

Preferably, to simplify the implementation of the step of depositing the thin intermetallic layer 110, it is produced from a target consisting of a composite of at least two metals. Moreover, the results obtained during tests demonstrate that the composition of the thin intermetallic layer 110 is more reproducible when the step of depositing the thin intermetallic layer 110 is implemented from a single target consisting of a metal composite.

By way of non-limiting example, the metals used are selected from Pt, Al, Cu, In and Au, or from composites of these metals.

More specifically, the metals are for example selected so that the thin intermetallic layer 110 includes an Au—Al, Au—In, Pt—Al, or Pt—Al—Cu intermetallic combination.

The deposition step is performed so that said thin intermetallic layer 110 measures between 20 and 1000 nm of thickness, preferably between 200 and 500 nm, and more preferably 300 nm. Thus, the thin intermetallic layer 110 is advantageously opaque and has a good compromise between a thickness thick enough in order that the thin intermetallic layer 110 is adapted to withstand mechanical stresses that it is likely to undergo, and a thickness thin enough in order that the consumption of noble metals and that the duration for depositing the thin intermetallic layer 110 are not too high.

The method of depositing the thin intermetallic layer 110 is implemented so that said thin intermetallic layer 110 has a mainly amorphous and slightly crystalline phase after its deposition.

The parameters of the PVD deposition method, particularly the powers applied simultaneously on the various sources, as well as the composition of the composite target if applicable, are selected so that the thin intermetallic layer 110 obtained has a composition that has a desired final colour after the step of depositing the thin intermetallic layer 110.

By way of non-limiting example, the thin intermetallic layer 110 may be made of Pt—Al—Cu composite the composition of which is Pt 48.2% by weight, Al 11.2% by weight and Cu 40.6% by weight, the deposition step being performed by cathodic co-sputtering from 3 pure targets respectively of Pt, Al and Cu. At the end of the deposition step, an external part is obtained, including a thin intermetallic layer slightly crystallised and a colour characterised by the parameters (L*, a*, b*)=(81.2, 6.6, 14.8). It therefore has a final orange colour.

Similarly, by way of non-limiting example, the thin intermetallic layer 110 may be made of Pt—Al—Cu composite the composition of which is Pt 36.7% by weight, Al 14.3% by weight and Cu 49.0% by weight, the deposition step being performed by cathodic co-sputtering from 3 pure targets respectively of Pt, Al and Cu. At the end of the deposition step, an external part is obtained, including a thin intermetallic layer slightly crystallised and a colour characterised by the parameters (L*, a*, b*)=(78.3, 6.5, 4.4). It therefore has a final pink colour.

In another non-limiting example, the thin intermetallic layer 110 may be made of Pt—Al—Cu composite the composition of which is Pt 54.6% by weight, Al 12.8% by weight and Cu 32.7% by weight, the deposition step being performed by cathodic co-sputtering from 3 pure targets respectively of Pt, Al and Cu. At the end of the deposition step, an external part is obtained, including a thin intermetallic layer slightly crystallised and a colour characterised by the parameters (L*, a*, b*)=(81.8, 4.3, 12.8). It therefore has a final yellow colour.

Advantageously, although the method does not require the implementation of an annealing step on the entire external part to obtain a predetermined colour, it may include a localised annealing step on a predetermined area 111 of the thin intermetallic layer 110.

This localised annealing step has the effect of locally modifying the final colour of the thin intermetallic layer 110, in order to generate a decoration, for example in the form of indices of dials, digits, logos, etc. Indeed, the annealing has the effect of locally modifying the phase of the thin intermetallic layer 110, by making it change from a mainly amorphous and slightly crystalline state to a crystalline state, which changes its colour, typically from its original hue to grey.

The localised annealing step is performed with the aid of a laser the beam of which may have a diameter for example between 10 μm and 100 μm, or even between 50 μm and 100 μm. The movement of the laser beam is advantageously controlled by a scanning system specific to the laser and based on mechanical or optical axes or by a scanning system specific to the substrate based on mechanical axes providing a high precision of the position of the point of impact of the laser beam on the thin intermetallic layer 110.

The laser beam has the effect of generating locally, at the point of impact with the thin intermetallic layer 110, a local rise of the temperature resulting in a local phase change of said thin intermetallic layer 110, and consequently in a local change of colour.

The laser beam may be generated by a nanosecond pulsed or microsecond pulsed laser, or optionally by a continuous laser.

More specifically, during the localised annealing step, the laser may emit pulses of a duration between 4 ns and 350 ns, of variable frequency between 10 kHz and 1 MHz, and that may reach an average power in the order of 40 W.

Alternatively, the localised annealing step may also be implemented by using picosecond or femtosecond pulsed lasers, by using the heat accumulation effect at high rate in frequencies ranging from 100 to 200 kHz up to 10 MHz, or pulse series in bursts, as known by the person skilled in the art, spaced apart from one another from a few picoseconds to a few nanoseconds.

The wavelength of the laser beam is determined so as to favour the absorbance of the material of the thin intermetallic layer 110 that the beam is intended to impact.

By way of example, the laser beam may have a wavelength in the infra-red spectrum, in the visible spectrum or in the ultraviolet spectrum.

During the localised annealing step, the variation of the energy of the pulses of the laser beam, their repetition frequency as well as their degree of superposition result in modifying the colour of the intermetallic layer 110.

It is thus possible to create multicoloured or contrasted decorations based on a single deposition of thin intermetallic layer 110 of homogeneous composition.

Advantageously, the steps of depositing and localised annealing the thin intermetallic layer may be preceded by a step of structuring the surface 112 of the substrate 100 wherein a portion 113 of the surface 112 of the substrate 100 is structured so as to generate a surface structure contrast on said surface 112.

In particular, the structured portion 113 of the surface 112 of the substrate 100 may correspond to the predetermined area 111 of the intermetallic layer 110 that is subjected to the heat treatment during the localised annealing step. This has the advantageous effect of reinforcing the difference between the visual appearance of said predetermined area 111 and that of the rest of the thin intermetallic layer 110.

Alternatively, in an alternative embodiment of the invention, the structuring is performed on the entire surface 112 of the substrate 100.

Such a surface structuring step may consist for example in polishing, matt finishing or satin finishing partially or totally the surface 112 of the substrate 100, according to the alternative embodiment considered.

In order to facilitate the localised annealing step and reduce the local contribution of heat needed to carry out the phase transformation of the thin intermetallic layer, the external part 10 may be preheated to a temperature that is close to the phase transition temperature. Thus the supplementary energy contribution by laser may be reduced.

Advantageously, the thin intermetallic layer 110 obtained after the deposition step may be covered with a protective layer 120, for example formed by a stack of dielectric layers intended to protect the thin intermetallic layer 110 against environmental hazards, during a subsequent deposition step that may advantageously be performed with the same deposition equipment as that used to implement the step for depositing the thin intermetallic layer 110. This stack of thin dielectric layers may also have the effect of modifying the visual appearance of the external part 10, for example by increasing the brightness thereof, and/or by modifying the colour of the intermetallic layer 110 by an advantageous interference effect.

The step of depositing a protective layer 120 is advantageously the last step of the method according to the invention.

The stack of thin dielectric layers may be formed of various oxides, nitrides, oxynitrides, such as TiO₂, Al₂O₃, SiO₂, SiN, Si3N4 and may be deposited by an ALD and/or PVD and/or CVD deposition method.

Alternatively, the step of depositing a protective layer 120 may consist in depositing a varnish layer, for example a polymer varnish layer of the zapon or parylene type.

Globally, if the method according to the invention includes all of the aforementioned steps, they are implemented successively by starting with the step of structuring the surface of the substrate 100, then the step of depositing a thin intermetallic layer 110 is performed, followed by the localised annealing step, and finally the step of depositing the protective layer 120.

The invention thus proposes a solution for the use of intermetallic compounds, particularly based on noble metals, offering a wide range of new colours for aesthetic applications in watchmaking, jewellery and any other luxury product.

More generally, it should be noted that the implementations and embodiments considered above have been described by way of non-limiting examples, and that other variants are consequently possible.

1. A method for depositing a coating on a substrate (100), comprising: depositing a thin intermetallic layer (110) formed of an intermetallic compound on said substrate (100), so as to obtain, at the end of this step, an external part (10) of a timepiece, jewellery or fashion items having a predetermined final colour.

2. The method according to claim 1, wherein the step of depositing the thin intermetallic layer (110) is performed by implementing a PVD deposition method from cathodic or ionic sputtering, thermal evaporation, arc or electron beam evaporation, or pulsed laser beam ablation.

3. The method according to claim 2, wherein the deposition of the thin layer is performed from at least one target consisting of a composite of at least two metals or of at least two targets of different pure metals.

4. The method according to claim 1, wherein the step of depositing the thin intermetallic layer (110) is performed so that said thin intermetallic layer (110) has a thickness between 20 and 1000 nm, preferably between 200 and 500 nm, and more preferably of 300 nm.

5. The method according to claim 1, further comprising a localised annealing step on a predetermined area (111) of the thin intermetallic layer (110) so as to locally modify the final colour of the external part (10).

6. The method according to claim 5, wherein the localised annealing step is performed by means of a laser the beam of which has a diameter between 10 μm and 100 μm.

7. The method according to claim 5, wherein the localised annealing step is performed by means of a laser configured to emit pulses the duration of which is between 4 ns and 350 ns, of variable frequency between 10 kHz and 1 MHz.

8. The method according to claim 6, wherein the localised annealing step is performed by means of a laser configured to emit pulses the duration of which is between 4 ns and 350 ns, of variable frequency between 10 kHz and 1 MHz.

9. The method according to claim 5, wherein the step of depositing the thin intermetallic layer (110) is preceded by a surface structuring step wherein the surface (112) of the substrate (100) is structured.

10. The method according to claim 9, wherein the localised annealing step is performed by means of a laser configured to emit pulses the duration of which is between 4 ns and 350 ns, of variable frequency between 10 kHz and 1 MHz, and wherein during the structuring step, only one portion (113) of the surface (112) of the substrate (100) is structured, said portion (113) corresponding to the predetermined area (111) of the thin intermetallic layer (110) subjected to the localised annealing step.

11. The method according to claim 9, wherein during the structuring step, the structuring is performed on the entire surface (112) of the substrate (100).

12. The method according to claim 1, comprising, after the step of depositing the thin intermetallic layer (110) and the possible step of localised annealing, a step of depositing a protective layer (120).

13. The method according to claim 12, wherein during the step of depositing the protective layer (120), the thin intermetallic layer (110) is covered by a stack of thin dielectric layers and/or by a translucent polymer layer.

14. The method according to claim 12, wherein during the step of depositing the protective layer (120), the composition and the thickness of the thin dielectric layers of the protective stack (120) are specifically selected to conserve the original colour of the thin intermetallic layer (110) or to advantageously modify the colour of the thin intermetallic layer (110) in a chosen direction.

15. A timepiece component comprising a substrate (100), comprising a coating deposited by implementing a method according to claim 1, said timepiece component having a predetermined final colour.
